(19) United States
(12) Patent Application Publication
(10) Pub. No.: US 2026/0304645 A1
(43) Pub. Date: Oct. 1, 2026

(54) FORMING A CIRCUIT BEARING STRUCTURE WITH PARTICLE-FREE METAL INK

(71) Applicant: LCP MEDICAL TECHNOLOGIES, LLC, Rogers, MN (US)

(72) Inventor: James Rathburn, Rogers, MN (US)

(21) Appl. No.: 19/478,310

(22) PCT Filed: Apr. 25, 2024
(86) PCT No.: PCT/US2024/026203

§ 371 Date: Oct. 24, 2025

Related U.S. Application Data
(60) Provisional application No. 63/498,104, filed on Apr. 25, 2023.

(51) Int. Cl. H05K 3/46; H05K 3/00; H05K 3/10

(52) U.S. Cl. CPC H05K 3/4644; H05K 3/0011; H05K 3/107

(57) ABSTRACT

Embodiments for a method of forming a circuit bearing structure are provided. The method includes coating a first surface of a dielectric layer of a substrate with particle-free metal ink and sintering the particle-free metal ink to form a metal layer on the first surface of the dielectric layer.

### RELATED APPLICATIONS

This application claims the benefit of U.S. Provisional Application No. 63/498,104, filed on Apr. 25, 2023, and entitled “PRINTED ELECTRICAL CIRCUIT STRUCTURES WITH NON-PARTICLE INK METALLIZATION ALTERNATIVE TO ELECTROLESS COPPER PLATING”, which is hereby incorporated herein by reference.

### BACKGROUND

Traditional printed circuits are often constructed in either rigid or flexible formats. In a rigid format, the printed circuit board (PCB) is a laminate of materials including circuits that when completed is stiff and cannot bend significantly without damage. Flexible circuits have become popular more recently in many applications where the ability to bend the circuit to connect one member of a system to another has some benefit. These flexible circuits are made in a similar manner to rigid PCBs, where layers of circuitry and dielectric are laminated. The main difference is the material set used for construction. Typical flexible circuits start with a polymer film that is clad, laminated, or deposited with copper. A photolithography image with the desired circuit geometry is printed onto the copper, and the film is etched to remove the unwanted materials. The films are processed similar to that of rigid PCBs with a series of imaging, masking, drilling, via creation, plating, trimming, etc. The resulting circuit is flexible in such a way that as it is bent, the polymer film bends and supports the copper circuitry in a way that it does not crack or break. These circuits are solderable and can have devices attached to provide some desired function. They are used in many electronic systems such as notebook computers, medical devices, displays, handheld devices, automobiles, and aircraft. These flexible materials can be used in high frequency applications where the material set and design features can often provide better electrical performance than a comparable rigid circuit.

Both rigid and flexible circuits are connected to the system in a variety of ways. In most cases, a portion of the circuitry is exposed to create a connection point in terminal. Once exposed, the terminal can be connected to another circuit or component by soldering, conductive adhesive, thermosonic welding, pressure, or some sort of connector.

Electroless copper plating is often used when constructing rigid or flexible circuits, where the dielectric materials are conditioned to accept the electroless copper to create a thin conductive coating which is subsequently used for adding thicker copper in an electroplating process. Electrolytic copper plating will only deposit copper onto a conductive surface, so the electroless copper is used to initiate electrolytic copper by acting as a conductive plating bus whereby copper will deposit out of solution when a current is applied. Non-conductive dielectric materials, however, can be difficult to metalize with electroless copper, resulting in a primary area of concern for reliability of the circuit being adhesion of the electroless copper to the dielectric.

### BRIEF DESCRIPTION

Embodiments for a method of forming a circuit bearing structure are provided. The method includes coating a first surface of a dielectric layer of a substrate with particle-free metal ink and sintering the particle-free metal ink to form a metal layer on the first surface of the dielectric layer.

### DRAWINGS

Understanding that the drawings depict only exemplary embodiments and are not therefore to be considered limiting in scope, the exemplary embodiments will be described with additional specificity and detail through the use of the accompanying drawings, in which:

FIGS. 1A-1J are cross-sectional cut-away views of example stages in a process of creating a circuit bearing structure using particle-free metal ink;

FIGS. 2A and 2B are cross-sectional cut-away views of example stages in another process of creating a circuit bearing structure using particle-free metal ink;

FIGS. 3A and 3B are cross-sectional cut-away views of example stages in a process of adding a layer to a circuit bearing structure formed in accordance with the process of FIGS. 2A and 2B; and

FIGS. 4A and 4B are cross-sectional cut-away views of example stages in another process of adding layers to a circuit bearing structure.

### DETAILED DESCRIPTION

Electroless copper plating is a complex process with many chemicals, solutions, and processes that must be controlled with time, temperature, and chemical make-up and have significant waste treatment needs to deal with the aftermath of the process. Surface preparation of the dielectric is important to provide acceptable adhesion of the electroless copper. Consistency of the deposition across the entire intended circuit can also be a challenge that impacts reliability and yield.

The subject matter described herein utilizes non-particle metallization inks that can be printed onto the dielectric surface in a controlled manner to provide an alternative to electroless copper plating. This ink deposition can be done to cover an entire surface or can be deposited in select locations to create circuit traces or features.

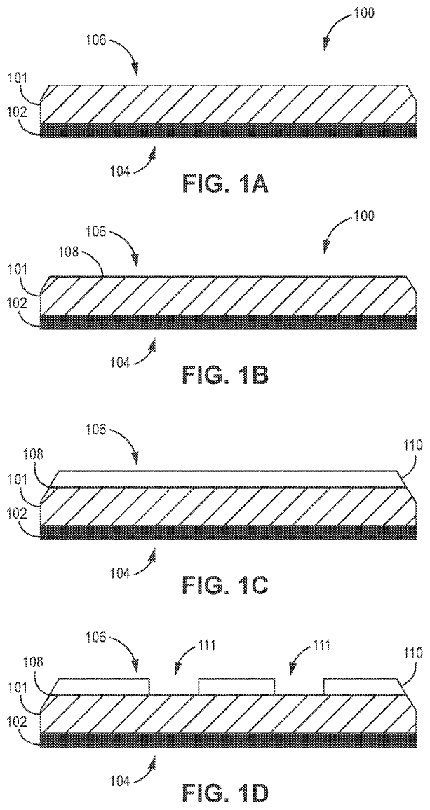

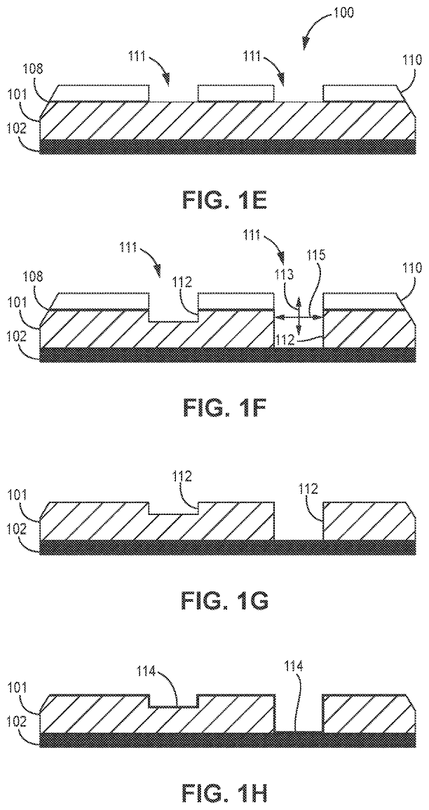

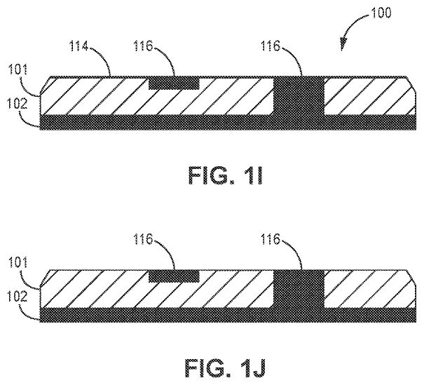

FIG. 1A is a cross-sectional cut-away view of an example portion of a substrate 100 onto which a circuit can be fabricated as described herein. The substrate 100 can include one or more dielectric layers 101. Each dielectric layer 101 can be composed of a dielectric material, such as liquid crystal polymer (LCP), polyimide, or Ajinomoto Build-Up Film® (ABF) produced by Ajinomoto Fine-Techno Co., Inc. LCP has many benefits from an electrical and mechanical standpoint. It has a lower dielectric constant than traditional PCB dielectric materials, can be processed to accept direct metal deposition, does not absorb moisture, and has low loss at high frequencies. The dielectric layer 101 can be a preformed film, or can be injection molded, printed, or compression molded to form a planar film having a desired thickness. In an example, the dielectric layer 101 is less than 200 microns thick. The composition of each dielectric layer 101 can be selected to have desired dielectric properties. One or more of the dielectric layers 101 can be clad with a copper layer 102 on a first surface 104 and have the bare dielectric layer exposed on a second surface 106, reverse of the first surface 104. The copper layer 102 can be deposited or laminated onto a dielectric layer 101 or can be a copper film that is laminated to a dielectric layer 101 and etched down to a thickness of 10 microns or less. Although FIG. 1A illustrates substrate 100 having a single dielectric layer 101 with no circuit features formed therein, in other examples the substate 100 includes more than one dielectric layer (e.g., a stack of dielectric layers) each of which may or may not have circuit features defined therein or thereon.

To fabricate a circuit in the dielectric layer 101, recesses are formed. FIGS. 1B-1F are cross-sectional views of the example substrate of FIG. 1A, showing example stages in forming such recesses.

In FIG. 1B, a layer of metal (e.g., copper) 108 is deposited on the second surface 106 of the dielectric layer 101. The metal layer 108 can be 10 microns or less thick, for example, between about 1 and 5 microns thick. The metal layer 108 can be formed by coating the second surface 106 of the dielectric layer 101 with particle-free metal ink. Particle-free metal ink is a liquid that includes metal ions, metal molecules, and/or metal salts along with volatile solvents in a solution. The metal ions, molecules, and/or salts can include copper and/or palladium and have a size less than 1 micron. The surface of the dielectric layer 101, can be conditioned to accept particle-free metal ink prior to coating. Conditioning the dielectric layer 101 can include roughening the surface to improve the bond between the dielectric and the particle-free ink. Some dielectrics have a smooth surface that can be adhesion resistant. Conditioning such a surface with O₂ plasma, permanganate, or applying a primer can create a slight porosity, roughened, or activated surface that improves a chemical and mechanical bond and increases the peel strength of the bond to reduce risk of separation during use or temperature excursions.

Once the particle-free ink is coated on the surface, the particle-free metal ink can be sintered to drive metal deposition out of solution to create a layer of solid metal 108 on the second surface 106 of the dielectric layer 101. Sintering can include treating the particle-free metal ink with a thermal excursion or plasma atmosphere, which causes the metal in the particle-free metal ink to deposit as the solvent evaporates. The resultant deposition is ideally entirely bulk metal, although some oxide may be present depending on the purity of the solution and the atmosphere as the solvent is evaporated.

In an alternative example, the metal layer 108 can be formed via known electroless copper deposition techniques or can be a copper film that is laminated to the dielectric layer 101 and etched down to a thickness of 10 microns or less.

In FIG. 1C, a resist 110 is deposited on the second surface 106 on top of the metal layer 108. The resist 110 can be composed of any suitable material. In FIG. 1D, the resist 110 is imaged and stripped to cure portions of the resist that are not overtop of desired circuit locations 111 and to remove portions of the resist that are overtop of desired circuit locations 111, thereby exposing the metal layer 108 in the desired circuit locations 111. In FIG. 1E, the exposed portions of the metal layer 108 are chemically etched away to expose the dielectric layer 101 in the desired circuit locations 111.

In FIG. 1F, recesses 112 are formed in the dielectric layer 101 at the desired circuit locations 111. The recesses 112 can be formed via laser ablation, such as UV laser ablation, excimer, CO₂ lasers or a green laser. UV laser ablation typically produces a cleaner ablation with reduced ash or deposition of residual particulates. Green laser with picosecond pulses is also a good option as the very short pulses do not heat the surrounding material adjacent to the ablation zone. The power/intensity and wavelength of the laser can be selected to ablate the dielectric layer 101 without removing or altering the disposition of the metal layer 108 adjacent to the exposed dielectric layer 101. A power setting resulting in beam intensity of less than one watt can be used for precision ablation without burning or heat effects, carbon deposition in the ablation zone, and containing the heat zone to the area being ablated and not effecting the nearby material. In this way, the metal layer 108 acts as a mask for the laser, which reduces the amount of dielectric layer 101 that is removed underneath the metal layer 108 thereby forming a recess with straighter sides. This can also reduce heat effects on the dielectric layer 101 in the area around the recesses 112. The resist 110 can be left in place during the laser ablation or removed prior to laser ablation. The length of time that the laser ablation is performed can be controlled to control the depth 113 of the recess. For circuit locations that will be traces or other features extending in parallel with the planar dielectric layer 101, the recesses 112 can extend part way through the dielectric layer 101 such that a portion of the dielectric layer 101 remains overtop of the base copper layer 102. For circuit locations that will be vias or other features extending all the way through the substrate, the recesses 112 can extend all the way through the dielectric layer 101 to the copper layer 102 on the first surface 104.

In an example, a pico-second laser can be used for the laser ablation. Advantageously, the above process using the metal layer 108 as a mask enables a recess 112 to be formed having a width 115 that is smaller than a spot size of the laser used for the laser ablation. Since the metal layer 108 blocks ablation of the dielectric layer 101 as discussed above, a recess can be formed smaller than the spot size of the laser by etching the metal layer 108 such that a width between adjacent edges of the etched metal layer 108 is less than the spot size of the laser. A laser having a spot size of, for example, 20 microns can therefore be used to form a recess having a width of 15 microns by etching the metal layer 108 such that a width between adjacent edges of the etched metal layer 108 is 15 microns. Laser power that is incident on areas outside of the exposed dielectric layer 101 is blocked by the metal layer 108. Thus, the width of a recess 112 and corresponding circuit feature is controlled by the width of the opening formed in the metal layer 108 as described with respect to FIGS. 1B-1E. Since the width of the etching of the metal layer 108 is based on the width of the recess formed in the resist 110, a width between adjacent edges of the etched metal layer 108 smaller than the spot size of the laser can be created by imaging the resist such that the stripped recesses formed in the resist 110 have a width smaller than the spot size of the laser.

Another advantage to using a laser having power, intensity, and wavelength selected to ablate the substrate 110 but not ablate copper is that when forming a recess 110 that extends all the way through the substrate 110, the laser will not damage or penetrate the base copper layer 102. This reduces unintended short or open circuits when plating operations are performed to form the via. This also creates a clean base metal target for plating with minimal residue deposits, which can be present in mechanically drilled vias. Such residue is typically removed by plasma treatment, which can create failure points with poor plating and/or mechanical strength at the base of the via. The laser ablation technique described herein can eliminate the need to perform the plasma treatment, thus eliminating a step and its potential side effects.

In FIG. 1G, the resist 110 can be removed and the remaining metal layer 108 can then be etched away. In other examples, the recesses 110 are formed in alternative manners including via laser ablation on the bare dielectric layer 101 shown in FIG. 1A. In yet other examples, the resist 110 and/or the remaining metal layer 108 shown in FIG. 1F are left on the dielectric layer 101 for plating of the recesses 112. In any case, the exposed surface of the dielectric layer 101, whether the entire dielectric layer 101 or just the recesses 112 is conditioned to accept particle-free metal ink.

In FIG. 1H, the exposed surface of the dielectric layer 101 is then coated with particle-free metal ink (e.g., copper or palladium). Such particle-free ink can be printed onto surfaces of the recesses 110 and/or the entire surface of the dielectric layer 101. The particle-free metal ink can then be sintered to drive metal deposition out of solution to create a layer of solid metal 114 on surfaces where the particle-free metal ink was coated. The metal layer 114 can be about between about 1 and 5 microns thick.

In FIG. 11, additional metal is added to the recesses 112 to form circuit features 116 (e.g., traces, vias) in the recesses 112. In a first implementation, the additional metal is added via copper electroplating. In such an implementation, the layer of metal 114 on the dielectric layer 101, including within the recesses 110, is used as an electrical bus for the copper electroplating to achieve a thicker layer of copper. In an example of this first implementation, the resist 110 shown in FIG. 1F can be left on the substrate (i.e., the step shown in FIG. 1G is not performed) during electroplating. This reduces the amount of copper deposition on areas outside of the recesses 112, which reduces the amount of copper that must be removed post plating. If the resist 110 is removed from the substrate prior to copper deposition, excess copper on the substrate can be removed by etching or mechanical abrasion. In an example, a plating chemistry that is engineered to deposit copper only into the recesses 112 (i.e., only into “defects” in the surface) can be used.

In an alternative implementation, additional metal is added in the recesses 112 via additional coating of the surfaces of the recess 112 with particle-free metal ink and sintering the ink. The additional particle-free copper ink (e.g., copper or palladium) and sintering can occur multiple times to deposit multiple layers (e.g., about 3 microns thick each) and fill the recesses 112. Advantageously, if the recesses 112 are filled with additional metal via successive layers of particle-free metal ink, the metal can be selectively added to the recesses 112 without adding significant metal outside of the recesses 112 by controlling where the particle-free metal ink is printed onto the dielectric layer 101. This reduces the amount of cooper that must be removed post plating.

In an example, enough additional metal is added to fill the recesses 110 to create circuit features formed of solid metal. In an alternative example, one or more of the recesses 110 have additional metal added to surfaces thereof, but the recesses 110 are not filled, for example, in order to form a hollow conductive feature such as a via.

In FIG. 1J, the layer of metal 114 outside of the circuit features 116 (i.e., between adjacent circuit features) is etched away. In some examples, the base copper layer 102 can also be etched away. The resulting structure includes a dielectric layer 101 having circuit features 116 formed therein.

In an example, an additional layer of metal can be added to select circuit features 116 as a finish for surface mounting pads. The additional layer of metal can be formed by coating and sintering the exposed surface of the circuit features 116 with a particle-free ink having a different chemistry, such as particle-free silver, gold, or palladium ink.

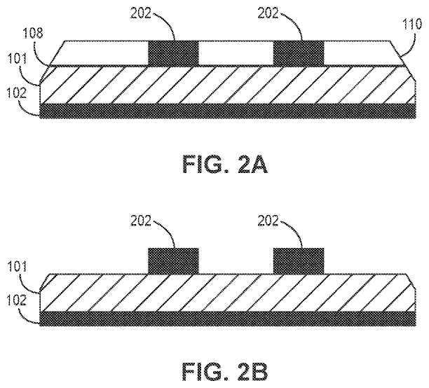

FIG. 2A is a cross-sectional cut-away view of an alternative process in which circuit features are created on top of the dielectric layer 101. This process can start with the same sequence shown in FIGS. 1A-1D. After the resist 110 is imaged and stripped, metal can be added in the recesses formed in the resist 110 to form circuit features. In an example, the metal is added via copper electroplating with the layer of metal 108 as the electrical bus. In this example, the resist 110 restricts the deposition of copper to the recesses, forming circuit features 202 on top of the dielectric layer 101. In an alternative example, metal can be added to the recesses via successive layers of particle-free metal ink coated on the surfaces of the recesses and sintered.

In FIG. 2B, the resist 110 is stripped away after plating along with the layer of metal 108 outside of the circuit features 202. This leaves circuit features 202 standing proud on the surface of the dielectric layer 101 without metal extending between adjacent circuit features.

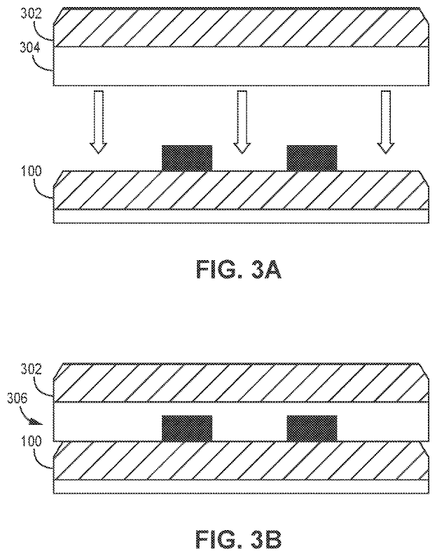

Any of the processes described herein can be repeated multiple times to create a structure (e.g., PCB) having multiple layers of circuits therein. FIGS. 3A and 3B are cross-sectional cut-away views of a process of adding a layer to a dielectric layer 101 having circuit features thereon or therein. In FIG. 3A, a second layer of dielectric 302 is bonded to the dielectric layer 101 having circuit features 202 thereon. A bond layer 304 is disposed between the dielectric layer 302 and the dielectric layer 101. The bond layer 304 can be a solid sheet of dielectric or a liquid dielectric. A liquid dielectric can flow between the circuit features 202 to encapsulate the circuit features 202 and create an air-free bond. Such a liquid dielectric can be composed of liquid and dielectric powder to create a low loss liquid. The bond layer 304 can also be entirely in powder form, including dielectric (e.g., LCP) powder that is disposed between the dielectric layer 302 and the dielectric layer 101. In any case, the bond layer can be heated and pressed in a lamination cycle to fusion bond the dielectric 302 to the dielectric layer 101 without substantially melting the dielectric 302 or dielectric layer 101. More detail on bonding a dielectric layer 302 to a dielectric layer 101 with dielectric powder as a bond layer is provided in PCT Application No. PCT/US2024/017576, entitled “LIQUID CRYSTAL POLYMER DIELECTRIC POWDER OR 3D PRINTED MATERIAL”, filed on Feb. 27, 2024, and which is hereby incorporated herein by reference.

FIG. 3B illustrates the resulting structure (e.g., PCB) having multiple layers of dielectric 100, 302 with a circuit layer 306 therebetween. One or more (e.g., all) of the additional dielectric layers can have a thickness of less than 200 microns. The same process shown in FIGS. 3A and 3B can be used for substrates 100 having circuit features disposed within the dielectric layer 101. Additional circuit features can then be formed in or on the dielectric layer 302 using any of the processes described herein. This sequence of adding dielectric layers and forming circuit features can be repeated multiple times to create a structure having multiple layers of circuits therein.

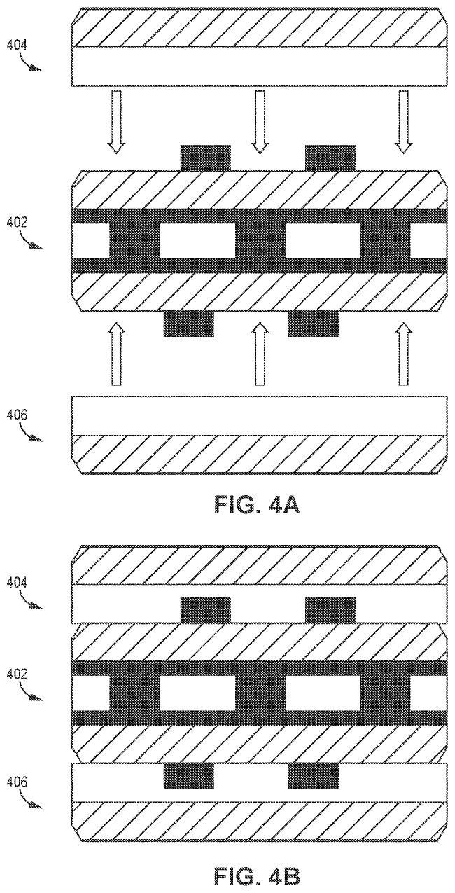

FIGS. 4A and 4B are cross-sectional cut-away views of another example structure (e.g., PCB) including a core 402 in which additional layers 404, 406 are added to both sides of the core 402. One or more (e.g., all) of the additional dielectric layers 404, 406 can have a thickness of less than 200 microns. The core 402 includes circuit features and vertical solid metal vias for creating the desired circuit network through the stack and terminating to surface mounting pads (not shown).

Although a certain type, size, and number of dielectric layers and circuit bearing structures are shown in FIGS. 1-4 herein, it should be understood that any number, size, or type of layers and/or circuit bearing structures in or on a layer can be created using the processes described herein, unless specifically limited by the corresponding description.

Advantageously, the use of particle-free metal (e.g., copper) ink can reduce or eliminate the need for electroless copper plating within a printed circuit construction. This benefit can have significant environmental impacts as electroless copper is a complex process that has chemical and waste treatment requirements that can be extensive. The particle-free ink can also be used as an alternative to electrolytic copper plating for the creating of circuit traces and vertical via connections. Noble metal particle-free ink, such as silver, gold, or palladium, can be used for the particle-free metal inks described herein as an alternative to conventional electroless or electrolytic noble metal plating for a solderable interface at surface mount pad locations of a circuit stack. These noble metal particle-free inks can also be used for the circuit features themselves, for example, for implantable or medical applications where copper content is not desired.

What is claimed is:

1. A method of forming a circuit bearing structure, the method comprising:
providing a substrate having a dielectric layer defining a first surface;
coating the first surface of the dielectric layer with particle-free metal ink; and
sintering the particle-free metal ink to form a metal layer on the first surface of the dielectric layer.

2. The method of claim 1, comprising:
forming recesses in the first surface of the substrate;
coating surfaces of the recesses with particle-free metal ink;
sintering the particle-free metal ink to form a metal layer on the surfaces of the recesses;
adding additional metal to the recesses to form circuit features in the recesses; and
etching the metal layer on the first surface of the dielectric layer outside of the recesses such that metal does not extend on the first surface of the dielectric layer between adjacent circuit features.

3. The method of claim 2, wherein adding additional metal includes electroplating copper using the metal layer on the surfaces of the recesses as an electrical bus.

4. The method of claim 2, wherein adding additional metal includes filling the recesses such that the circuit features are solid metal.

5. The method of claim 4, wherein adding additional metal includes placing additional particle-free metal ink in the recesses and sintering the additional particle-free metal ink.

6. The method of claim 2, wherein forming recesses in the first surface of the dielectric layer includes:
placing a resist layer on the metal layer;
imaging and stripping the resist layer to expose the metal layer in areas corresponding to circuit features;
etching the metal layer that is exposed by the resist layer to expose the dielectric layer in areas corresponding to the circuit features; and
ablating the dielectric layer with a laser to form the recesses in the areas corresponding to the circuit features, wherein a power and a wavelength of the laser are set such that the laser does not ablate the metal layer.

7. The method of claim 6, wherein imaging and stripping the resist layer includes forming at least one recess in the resist layer having a width smaller than a spot size of the laser, such that a corresponding circuit feature has a width smaller than the spot size of the laser.

8. The method of claim 6, comprising:
removing remaining portions of the resist layer on the metal layer after adding additional metal to the recesses in the first surface of the dielectric layer.

9. The method of claim 2, comprising:
bonding one or more additional dielectric layers to the substrate; and
forming additional circuit features in or on at least one of the one or more additional dielectric layers.

10. The method of claim 2, wherein the metal layer on the surfaces of the recesses is between about 1 and 5 microns thick.

11. The method of claim 1, comprising:
placing a resist layer on the metal layer;
imaging and stripping the resist layer to form recesses in the resist layer and expose the metal layer in areas corresponding to circuit features;
adding metal to the recesses to form circuit features;
removing remaining portions of the resist layer on the metal layer; and
etching the metal layer on the first side of the substrate outside of the recesses such that metal does not extend on the first side of the substrate between adjacent circuit features.

12. The method of claim 11, wherein adding metal includes electroplating copper using the metal layer on the first side of the substrate as an electrical bus.

13. The method of claim 11, wherein adding additional metal includes forming additional layers of metal in the recesses, each layer formed by printing particle-free metal ink in the recesses and sintering the particle-free metal ink.

14. The method of claim 11, comprising:
bonding one or more additional dielectric layers to the substrate; and
forming additional circuit features in or on at least one of the one or more additional dielectric layers.

15. A method of forming a circuit bearing structure, the method comprising:
providing a substrate having a dielectric layer and a copper layer on a first surface of the dielectric layer, wherein the copper layer is less than 10 microns thick;
placing a resist layer on the copper layer;
imaging and stripping the resist layer to expose the copper layer in areas corresponding to circuit features;
etching the copper layer that is exposed by the resist layer to expose the dielectric layer in areas corresponding to the circuit features;
ablating the dielectric with a laser to form recesses in the dielectric layer in the areas corresponding to the circuit features, wherein a power and a wavelength of the laser are set such that the laser does not ablate the copper layer;
coating surfaces of the recesses with particle-free metal ink;
sintering the particle-free metal ink to form a metal layer on surfaces of the recesses;
adding additional metal to the recesses to form circuit features in the recesses; and
etching the metal layer on the first surface of the dielectric layer outside of the recesses such that metal does not extend on the first surface of the dielectric layer between adjacent circuit features.

16. The method of claim 15, wherein adding additional metal includes electroplating copper using the metal layer on surfaces of the recesses as an electrical bus.

17. The method of claim 15, wherein adding additional metal includes filling the recesses such that the circuit features are solid metal.

18. The method of claim 17, wherein adding additional metal includes placing additional particle-free metal ink in the recesses and sintering the additional particle-free metal ink.

19. The method of claim 15, wherein imaging and stripping the resist layer includes forming at least one recess in the resist layer having a width smaller than a spot size of the laser, such that a corresponding circuit feature has a width smaller than the spot size of the laser.

20. The method of claim 15, comprising:
removing remaining portions of the resist layer on the metal layer after adding additional metal to the recesses in the first surface of the dielectric layer.

21. The method of claim 15, comprising:
bonding one or more additional dielectric layers to the substrate; and
forming additional circuit features in or on at least one of the one or more additional dielectric layers.

22. A method of forming a circuit bearing structure, the method comprising:
providing a substrate having a dielectric layer and a copper layer on a first surface of the dielectric layer, wherein the copper layer is less than 10 microns thick;
placing a resist layer on the copper layer;
imaging and stripping the resist layer to form recesses in the resist layer and expose the copper layer in areas corresponding to circuit features;
placing particle-free metal ink in the recesses and sintering the particle-free metal ink to form circuit features;
removing remaining portions of the resist layer on the metal layer; and
etching the metal layer on the first surface of the dielectric layer outside of the recesses such that metal does not extend on the first surface of the dielectric layer between adjacent circuit features.

23. The method of claim 22, wherein adding additional metal includes filling the recesses such that the circuit features are solid metal.

24. The method of claim 22, comprising:
bonding one or more additional dielectric layers to the substrate; and
forming additional circuit features in or on at least one of the one or more additional dielectric layers.
